(19) United States
(12) Patent Application Publication
(10) Pub. No.: US 2024/0302164 A1
(43) Pub. Date: Sep. 12, 2024

(54) OPTICAL ELEMENT FOR USE IN METROLOGY SYSTEMS

(71) Applicant: ASML NETHERLANDS B.V., Veldhoven (NL)

(72) Inventors: Tzu-Yi YANG, Wilton, CT (US); Richard Carl ZIMMERMAN, Brookfield, CT (US); Adel JOOBEUR, Milford, CT (US); Yevgeniy Konstantinovich SHMAREV, Campbell, CA (US)

(73) Assignee: ASML NETHERLANDS B.V., Veldhoven (NL)

(21) Appl. No.: 18/580,062

(22) PCT Filed: Jul. 18, 2022
(86) PCT No.: PCT/EP2022/070108

§ 371 Date: Jan. 17, 2024

Related U.S. Application Data
(60) Provisional application No. 63/228,407, filed on Aug. 2, 2021.

(51) Int. Cl. G01B 11/27; G03F 7/00

(52) U.S. Cl. CPC G01B 11/272; G03F 7/70633; G03F 7/706849; G03F 7/706851

(57) ABSTRACT

An optical element, and a metrology tool or system employing the optical element for measurements of structures on a substrate. The optical element includes a first portion configured to reflect the light received from an illumination source towards the substrate, and a second portion configured to transmit the light redirected from the substrate or a desired location, the first portion having a higher coefficient of reflectivity than the second portion, and the second portion having a higher coefficient of transmissivity than the first portion. A metrology tool may include the optical elements and a sensor configured to receive a diffraction pattern caused by radiation redirected from a substrate, and a processor configured to receive a signal relating to the diffraction pattern from the sensor, and determine overlay associated with the substrate by analyzing the signal.

### CROSS-REFERENCE TO RELATED APPLICATIONS

This application claims priority of U.S. Provisional Patent Application No. 63/228,407, which was filed on Aug. 2, 2021, and which is incorporated herein in its entirety by reference.

### TECHNICAL FIELD

The description herein relates generally to improved metrology systems and methods for overlay measurement in a lithography process.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., including part of a die, one die, or several dies) on a substrate (e.g., a silicon wafer). Transfer of the pattern is typically via imaging onto a layer of radiation-sensitive material (resist) provided on the substrate. In general, a single substrate contains a plurality of adjacent target portions to which the pattern is transferred successively by the lithographic apparatus, one target portion at a time. In one type of lithographic apparatuses, the pattern on the entire patterning device is transferred onto one target portion in one go; such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. It is also possible to transfer the pattern from the patterning device to the substrate by imprinting the pattern onto the substrate.

### SUMMARY

Integrated circuits with features having reduced nanometer dimensions is desired and demand for these features to perform highly complex functionality is continually increasing. The amount of the functional elements, such as transistors, per device has been steadily increased over decades on a small chip. Such features are manufactured using semiconductor manufacturing process employing lithographic apparatus, metrology tools/systems, among others. Manufacturing such nano-scaled features with reduced size (e.g., 30 nm or less, or even 7 nm nanometer or less) puts more stringent requirements in accuracy in terms of overlay between features, critical dimension (CD) of the features, etc. To meet such requirements, the amount of metrology effort and time during the semiconductor manufacturing has increased significantly. In order to meet the increasing metrology effort and time within the desired throughput (e.g., number of wafers produced per hour) requirement of the semiconductor manufacturing, efficient metrology tools are needed. The present disclosure identifies existing optical components used in a metrology tool that can be further improved. For example, the present disclosure presents an optical element that improves efficiency of radiation utilization by three folds or more.

In one embodiment, the present disclosure sets forth an optical element configured to include a first portion with higher reflectivity than a second portion, and a second portion having a higher transmissivity than the first portion. In an embodiment, an optical tool comprising the optical element is provided. The optical tool includes an illumination source; an objective lens configured to direct light from the illumination source to a substrate or a desired location in the optical tool; and an optical element having a first portion configured to reflect the light received from the illumination source towards the substrate, and a second portion configured to transmit the light reflected from the substrate or the desired location in the optical tool. The first portion has higher coefficient of reflectivity (e.g., more than 51%) than the second portion, and the second portion having higher coefficient of transmissivity (e.g., more than 51%) than the first portion.

In an embodiment, the optical element is positioned at a distance within a specified range from a entrance pupil or a conjugate pupil of the objective lens, wherein the specified range is between the entrance pupil and a conjugate plane, and the distance is measured between a point on the first portion, and the entrance pupil or the conjugate pupil. In an embodiment, the specified range from the entrance pupil or a conjugate pupil is a range at which the optical element captures a diffraction pattern caused by the light directed from the first portion onto the substrate and diffracted from the substrate without causing vignetting.

In an embodiment, a system for measuring overlay of patterned substrates is provided. The system includes an illumination source to illuminate a patterned substrate; an optical element comprising a first portion configured to reflect light received from the illumination source, and a second portion configured to transmit the light reflected from the patterned substrate, the first portion having higher coefficient of reflectivity than the second portion, the second portion having higher coefficient of transmissivity than the first portion; a sensor configured to receive diffraction pattern caused by the patterned substrate; and a processor configured to receive signal comprising the diffraction pattern from the sensor, and determine overlay associated with the patterned substrate by analyzing the signal comprising the diffraction pattern.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed embodiments. In the drawings,

FIG. 1 illustrates a lithographic apparatus, according to an embodiment;

FIG. 2A illustrates schematically measurement and exposure processes in the apparatus of FIG. 1, according to an embodiment;

FIG. 2B illustrates a lithographic cell or cluster, according to an embodiment;

FIG. 3A is schematic diagram of a measurement apparatus for use in measuring targets according to an embodiment using a first pair of illumination apertures providing certain illumination modes;

FIG. 3B is a schematic detail of a diffraction spectrum of a target for a given direction of illumination, according to an embodiment;

FIG. 3C is a schematic illustration of a second pair of illumination apertures providing further illumination modes in using a measurement apparatus for diffraction based overlay measurements, according to an embodiment;

FIG. 3D is a schematic illustration of a third pair of illumination apertures combining the first and second pairs of apertures providing further illumination modes in using a measurement apparatus for diffraction based overlay measurements, according to an embodiment;

FIG. 4 schematically depicts a form of multiple periodic structure target and an outline of a measurement spot on a substrate, according to an embodiment;

FIG. 5 schematically depicts an image of the target of FIG. 4 obtained in the apparatus of FIG. 3A, according to an embodiment;

FIG. 6 schematically depicts an example metrology apparatus and metrology technique, according to an embodiment;

FIG. 7 schematically depicts an example metrology apparatus, according to an embodiment;

FIG. 8 illustrates an exemplary optical element, according to an embodiment;

FIG. 9A is an exemplary optical surface of an optical element configured to include a high reflective portion in a 1^{st} and 3^{rd} quadrant, and a high transmissive portion in a 2^{nd} and 4^{th} quadrant, according to an embodiment;

FIG. 9B is an exemplary optical surface of an optical element configured to include oval-shaped high reflective portions in a 1^{st} and 3^{rd} quadrant, and remaining portions being high transmissive portions, according to an embodiment;

FIG. 10 illustrates positioning of an exemplary optical element with respect to entrance pupil to prevent vignetting, according to an embodiment,

FIG. 11 is a block diagram of an example computer system for use in performing some of the methods described herein, according to an embodiment;

FIG. 12 is a schematic diagram of another lithographic projection apparatus (LPA), according to an embodiment;

FIG. 13 is a detailed view of the lithographic projection apparatus, according to an embodiment;

FIG. 14 is a detailed view of source collector module SO of lithographic projection apparatus LPA, according to an embodiment.

### DETAILED DESCRIPTION

The present disclosure will now be described in detail with reference to the drawings, which are provided as illustrative examples of the disclosure so as to enable those skilled in the art to practice the disclosure. Notably, the figures and examples below are not meant to limit the scope of the present disclosure to a single embodiment, but other embodiments are possible by way of interchange of some or all of the described or illustrated elements. Moreover, where certain elements of the present disclosure can be partially or fully implemented using known components, only those portions of such known components that are necessary for an understanding of the present disclosure will be described, and detailed descriptions of other portions of such known components will be omitted so as not to obscure the disclosure. Embodiments described as being implemented in software should not be limited thereto, but can include embodiments implemented in hardware, or combinations of software and hardware, and vice-versa, as will be apparent to those skilled in the art, unless otherwise specified herein. In the present specification, an embodiment showing a singular component should not be considered limiting; rather, the disclosure is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present disclosure encompasses present and future known equivalents to the known components referred to herein by way of illustration.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle,” “wafer” or “die” in this text should be considered as interchangeable with the more general terms “mask,” “substrate” and “target portion,” respectively.

In the present document, the terms “radiation” and “beam” used herein encompass all types of electromagnetic radiation, including visible radiation (for example, having a wavelength, in the range of 400 to 780 nm), ultraviolet (UV) radiation (for example, having a wavelength, of 365, 248, 193, 157 or 126 nm), extreme ultraviolet (EUV or soft X-ray) radiation (for example, having a wavelength in the range of 5-20 nm such as, for example, 13.5 nm), or hard X-ray working at less than 5 nm, as well as particle beams, such as ion beams or electron beams. Generally, radiation having wavelengths between about 780-3000 nm (or larger) is considered IR radiation. UV refers to radiation with wavelengths of approximately 100-400 nm. Within lithography, the term “UV” also applies to the wavelengths that can be produced by a mercury discharge lamp: G-line 436 nm; H-line 405 nm; and/or, I-line 365 nm Vacuum UV, or VUV (e.g., UV absorbed by air), refers to radiation having a wavelength of approximately 100-200 nm. Deep UV (DUV) generally refers to radiation having wavelengths ranging from 126 nm to 428 nm, and in an embodiment, an excimer laser can generate DUV radiation used within a lithographic apparatus. It should be appreciated that radiation having a wavelength in the range of, for example, 5-20 nm relates to radiation with a certain wavelength band, of which at least part is in the range of 5-20 nm.

The patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. One or more of the design rule limitations may be referred to as “critical dimension” (CD). A critical dimension of a device can be defined as the smallest width of a line or hole or the smallest space between two lines or two holes. Thus, the CD determines the overall size and density of the designed device. Of course, one of the goals in device fabrication is to faithfully reproduce the original design intent on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include a programmable mirror array and a programmable LCD array.

An example of a programmable mirror array can be a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The matrix addressing can be performed using suitable electronic means.

An example of a programmable LCD array is given in U.S. Pat. No. 5,229,872, which is incorporated herein by reference.

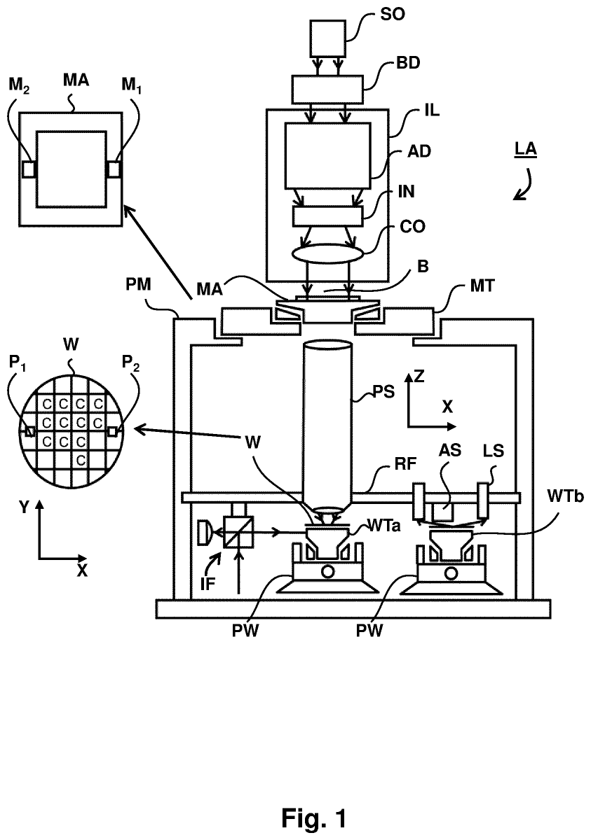

FIG. 1 is schematically a lithographic apparatus. The apparatus includes an illumination system (illuminator) IL configured to condition a radiation beam B (e.g., UV radiation or DUV radiation), a patterning device support or support structure (e.g., a mask table) MT constructed to support a patterning device (e.g., a mask) MA and connected to a first positioner PM configured to accurately position the patterning device in accordance with certain parameters; two substrate tables (e.g., a wafer table) WTa and WTb each constructed to hold a substrate (e.g., a resist coated wafer) W and each connected to a second positioner PW configured to accurately position the substrate in accordance with certain parameters; and a projection system (e.g., a refractive projection lens system) PS configured to project a pattern imparted to the radiation beam B by patterning device MA onto a target portion C (e.g., including one or more dies) of the substrate W. A reference frame RF connects the various components, and serves as a reference for setting and measuring positions of the patterning device and substrate and of features on them.

The illumination system may include various types of optical components, such as refractive, reflective, magnetic, electromagnetic, electrostatic or other types of optical components, or any combination thereof, for directing, shaping, or controlling radiation.

The patterning device support MT holds the patterning device in a manner that depends on the orientation of the patterning device, the design of the lithographic apparatus, and other conditions, such as for example whether or not the patterning device is held in a vacuum environment. The patterning device support can use mechanical, vacuum, electrostatic or other clamping techniques to hold the patterning device. The patterning device support MT may be a frame or a table, for example, which may be fixed or movable as desired. The patterning device support may ensure that the patterning device is at a desired position, for example with respect to the projection system.

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so-called assist features. Generally, the pattern imparted to the radiation beam will correspond to a particular functional layer in a device being created in the target portion, such as an integrated circuit.

As here depicted, the apparatus is of a transmissive type (e.g., employing a transmissive patterning device). Alternatively, the apparatus may be of a reflective type (e.g., employing a programmable mirror array of a type as referred to above, or employing a reflective mask). Examples of patterning devices include masks, programmable mirror arrays, and programmable LCD panels. Any use of the terms “reticle” or “mask” herein may be considered synonymous with the more general term “patterning device.” The term “patterning device” can also be interpreted as referring to a device storing in digital form pattern information for use in controlling such a programmable patterning device.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

The lithographic apparatus may also be of a type wherein at least a portion of the substrate may be covered by a liquid having a relatively high refractive index (e.g., water) so as to fill a space between the projection system and the substrate. An immersion liquid may also be applied to other spaces in the lithographic apparatus, for example, between the mask and the projection system. Immersion techniques are well known in the art for increasing the numerical aperture of projection systems.

In operation, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases, the source may be an integral part of the lithographic apparatus, for example when the source is a mercury lamp. The source SO and the illuminator IL, together with the beam delivery system BD if used, may be referred to as a radiation system.

The illuminator IL may for example include an adjuster AD for adjusting the angular intensity distribution of the radiation beam, an integrator IN and a condenser CO. The illuminator may be used to condition the radiation beam, to have a desired uniformity and intensity distribution in its cross section.

The radiation beam B is incident on the patterning device MA, which is held on the patterning device support MT, and is patterned by the patterning device. Having traversed the patterning device (e.g., mask) MA, the radiation beam B passes through the projection system PS, which focuses the beam onto a target portion C of the substrate W. With the aid of the second positioner PW and position sensor IF (e.g., an interferometric device, linear encoder, 2-D encoder or capacitive sensor), the substrate table WTa or WTb can be moved accurately, e.g., so as to position different target portions C in the path of the radiation beam B. Similarly, the first positioner PM and another position sensor (which is not explicitly depicted in FIG. 1) can be used to accurately position the patterning device (e.g., mask) MA with respect to the path of the radiation beam B, e.g., after mechanical retrieval from a mask library, or during a scan.

Patterning device (e.g., mask) MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device (e.g., mask) MA, the mask alignment marks may be located between the dies. Small alignment marks may also be included within dies, in amongst the device features, in which case it is desirable that the markers be as small as possible and not require any different imaging or process conditions than adjacent features. The alignment system, which detects the alignment markers, is described further below.

The depicted apparatus could be used in a variety of modes. In a scan mode, the patterning device support (e.g., mask table) MT and the substrate table WT are scanned synchronously while a pattern imparted to the radiation beam is projected onto a target portion C (e.g., a single dynamic exposure). The speed and direction of the substrate table WT relative to the patterning device support (e.g., mask table) MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. Other types of lithographic apparatus and modes of operation are possible, as is well-known in the art. For example, a step mode is known. In so-called “maskless” lithography, a programmable patterning device is held stationary but with a changing pattern, and the substrate table WT is moved or scanned.

Combinations and/or variations on the above-described modes of use or entirely different modes of use may also be employed.

Lithographic apparatus LA is of a so-called dual stage type which has two substrate tables WTa, WTb and two stations—an exposure station EXP and a measurement station MEA-between which the substrate tables can be exchanged. While one substrate on one substrate table is being exposed at the exposure station, another substrate can be loaded onto the other substrate table at the measurement station and various preparatory steps carried out. This enables a substantial increase in the throughput of the apparatus. The preparatory steps may include mapping the surface height contours of the substrate using a level sensor LS and measuring the position of alignment markers on the substrate using an alignment sensor AS. If the position sensor IF is not capable of measuring the position of the substrate table while it is at the measurement station as well as at the exposure station, a second position sensor may be provided to enable the positions of the substrate table to be tracked at both stations, relative to reference frame RF. Other arrangements are known and usable instead of the dual-stage arrangement shown. For example, other lithographic apparatuses are known in which a substrate table and a measurement table are provided. These are docked together when performing preparatory measurements, and then undocked while the substrate table undergoes exposure.

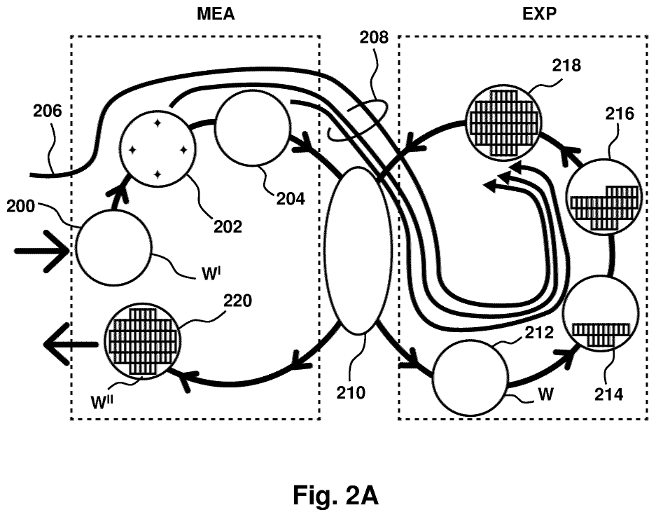

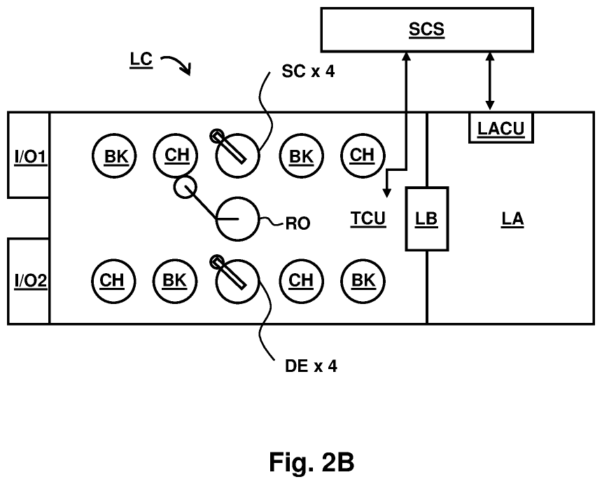

FIG. 2A illustrates schematically measurement and exposure processes in the apparatus of FIG. 1 which includes the steps to expose target portions (e.g. dies) on a substrate W in the dual stage apparatus of FIG. 1. On the left-handed side within a dotted box steps are performed at a measurement station MEA, while the right-handed side shows steps performed at the exposure station EXP. From time to time, one of the substrate tables WTa, WTb will be at the exposure station, while the other is at the measurement station, as described above. For the purposes of this description, it is assumed that a substrate W has already been loaded into the exposure station. At step 200, a new substrate W′ is loaded to the apparatus by a mechanism not shown. These two substrates are processed in parallel in order to increase the throughput of the lithographic apparatus.

Referring initially to the newly-loaded substrate W′, this may be a previously unprocessed substrate, prepared with a new photo resist for first time exposure in the apparatus. In general, however, the lithography process described will be merely one step in a series of exposure and processing steps, so that substrate W′ has been through this apparatus and/or other lithography apparatuses, several times already, and may have subsequent processes to undergo as well. Particularly for the purpose of improving overlay performance, the task is to ensure that new patterns are applied in the correct position on a substrate that has already been subjected to one or more cycles of patterning and processing. These processing steps progressively introduce distortions in the substrate that can be measured and corrected for to achieve satisfactory overlay performance.

The previous and/or subsequent patterning step may be performed in other lithography apparatuses, as just mentioned, and may even be performed in different types of lithography apparatus. For example, some layers in the device manufacturing process which are very demanding in parameters such as resolution and overlay may be performed in a more advanced lithography tool than other layers that are less demanding. Therefore, some layers may be exposed in an immersion-type lithography tool, while others are exposed in a “dry′” tool. Some layers may be exposed in a tool working at DUV wavelengths, while others are exposed using EUV wavelength radiation.

At 202, alignment measurements using the substrate marks P1, etc., and image sensors (not shown) are used to measure and record alignment of the substrate relative to substrate table WTa/WTb. In addition, several alignment marks across the substrate W′ will be measured using alignment sensor AS. These measurements are used in one embodiment to establish a “wafer grid,” which maps very accurately the distribution of marks across the substrate, including any distortion relative to a nominal rectangular grid.

At step 204, a map of wafer height (Z) against the X-Y position is measured also using the level sensor LS. Conventionally, the height map is used only to achieve accurate focusing of the exposed pattern. It may be used for other purposes in addition.

When substrate W′ was loaded, recipe data 206 were received, defining the exposures to be performed, and also properties of the wafer and the patterns previously made and to be made upon it. These recipe data are added to the measurements of wafer position, wafer grid, and height map that were made at 202, 204, and then a complete set of recipe and measurement data 208 can be passed to the exposure station EXP. The measurements of alignment data for example comprise X and Y positions of alignment targets formed in a fixed or nominally fixed relationship to the product patterns that are the product of the lithographic process. These alignment data, taken just before exposure, are used to generate an alignment model with parameters that fit the model to the data. These parameters and the alignment model will be used during the exposure operation to correct positions of patterns applied in the current lithographic step. The model in use interpolates positional deviations between the measured positions. A conventional alignment model might comprise four, five or six parameters, together defining translation, rotation and scaling of the “ideal” grid, in different dimensions. Advanced models are known that use more parameters.

At 210, wafers W′ and W are swapped, so that the measured substrate W′ becomes the substrate W entering the exposure station EXP. In the example apparatus of FIG. 1, this swapping is performed by exchanging the supports WTa and WTb within the apparatus, so that the substrates W, W′ remain accurately clamped and positioned on those supports, to preserve relative alignment between the substrate tables and substrates themselves. Accordingly, once the tables have been swapped, determining the relative position between projection system PS and substrate table WTb (formerly WTa) is all that is necessary to make use of the measurement information 202, 204 for the substrate W (formerly W′) in control of the exposure steps. At step 212, reticle alignment is performed using the mask alignment marks M1, M2. In steps 214, 216, 218, scanning motions and radiation pulses are applied at successive target locations across the substrate W, in order to complete the exposure of a number of patterns.

By using the alignment data and height map obtained at the measuring station, and the performance of the exposure steps, these patterns are accurately aligned with respect to the desired locations, and, in particular, with respect to features previously laid down on the same substrate. The exposed substrate, now labeled W″ is unloaded from the apparatus at step 220, to undergo etching or other processes, in accordance with the exposed pattern.

The skilled person will know that the above description is a simplified overview of a number of very detailed steps involved in one example of a real manufacturing situation. For example, rather than measuring alignment in a single pass, often there will be separate phases of coarse and fine measurement, using the same or different marks. The coarse and/or fine alignment measurement steps can be performed before or after the height measurement, or interleaved.

In one embodiment, optical position sensors, such as alignment sensor AS, use visible and/or near-infra-red (NIR) radiation to read alignment marks. In some processes, processing of layers on the substrate after the alignment mark has been formed leads to situations in which the marks cannot be found by such an alignment sensor due to low or no signal strength.

FIG. 2B illustrates a lithographic cell or cluster. the lithographic apparatus LA may form part of a lithographic cell LC, also sometimes referred to a lithocell or cluster, which also includes apparatuses to perform pre- and post-exposure processes on a substrate. Conventionally these include one or more spin coaters SC to deposit one or more resist layers, one or more developers DE to develop exposed resist, one or more chill plates CH and/or one or more bake plates BK. A substrate handler, or robot, RO picks up one or more substrates from input/output port I/O1, I/O2, moves them between the different process apparatuses and delivers them to the loading bay LB of the lithographic apparatus. These apparatuses, which are often collectively referred to as the track, are under the control of a track control unit TCU which is itself controlled by the supervisory control system SCS, which also controls the lithographic apparatus via lithography control unit LACU. Thus, the different apparatuses can be operated to maximize throughput and processing efficiency.

In order that a substrate that is exposed by the lithographic apparatus is exposed correctly and consistently, it is desirable to inspect an exposed substrate to measure or determine one or more properties such as overlay (which can be, for example, between structures in overlying layers or between structures in a same layer that have been provided separately to the layer by, for example, a double patterning process), line thickness, critical dimension (CD), focus offset, a material property, etc. Accordingly, a manufacturing facility in which lithocell LC is located also typically includes a metrology system MET which receives some or all of the substrates W that have been processed in the lithocell. The metrology system MET may be part of the lithocell LC, for example it may be part of the lithographic apparatus LA.

Metrology results may be provided directly or indirectly to the supervisory control system SCS. If an error is detected, an adjustment may be made to exposure of a subsequent substrate (especially if the inspection can be done soon and fast enough that one or more other substrates of the batch are still to be exposed) and/or to subsequent exposure of the exposed substrate. Also, an already exposed substrate may be stripped and reworked to improve yield, or discarded, thereby avoiding performing further processing on a substrate known to be faulty. In a case where only some target portions of a substrate are faulty, further exposures may be performed only on those target portions which are good.

Within a metrology system MET, a metrology apparatus is used to determine one or more properties of the substrate, and in particular, how one or more properties of different substrates vary or different layers of the same substrate vary from layer to layer. The metrology apparatus may be integrated into the lithographic apparatus LA or the lithocell LC or may be a stand-alone device. To enable rapid measurement, it is desirable that the metrology apparatus measure one or more properties in the exposed resist layer immediately after the exposure. However, the latent image in the resist has a low contrast—there is only a very small difference in refractive index between the parts of the resist which have been exposed to radiation and those which have not—and not all metrology apparatus have sufficient sensitivity to make useful measurements of the latent image. Therefore measurements may be taken after the post-exposure bake step (PEB) which is customarily the first step carried out on an exposed substrate and increases the contrast between exposed and unexposed parts of the resist. At this stage, the image in the resist may be referred to as semi-latent. It is also possible to make measurements of the developed resist image—at which point either the exposed or unexposed parts of the resist have been removed—or after a pattern transfer step such as etching. The latter possibility limits the possibilities for rework of a faulty substrate but may still provide useful information.

To enable the metrology, one or more targets can be provided on the substrate. In an embodiment, the target is specially designed and may comprise a periodic structure. In an embodiment, the target is a part of a device pattern, e.g., a periodic structure of the device pattern. In an embodiment, the device pattern is a periodic structure of a memory device (e.g., a Bipolar Transistor (BPT), a Bit Line Contact (BLC), etc. structure).

In an embodiment, the target on a substrate may comprise one or more 1-D periodic structures (e.g., gratings), which are printed such that after development, the periodic structural features are formed of solid resist lines. In an embodiment, the target may comprise one or more 2-D periodic structures (e.g., gratings), which are printed such that after development, the one or more periodic structures are formed of solid resist pillars or vias in the resist. The bars, pillars or vias may alternatively be etched into the substrate (e.g., into one or more layers on the substrate).

In an embodiment, one of the parameters of interest of a patterning process is overlay. Overlay can be measured using dark field scatterometry in which the zeroth order of diffraction (corresponding to a specular reflection) is blocked, and only higher orders processed. Examples of dark field metrology can be found in PCT patent application publication nos. WO 2009/078708 and WO 2009/106279, which are hereby incorporated in their entirety by reference. Further developments of the technique have been described in U.S. patent application publications US2011-0027704, US2011-0043791 and US2012-0242970, which are hereby incorporated in their entirety by reference. Diffraction-based overlay using dark-field detection of the diffraction orders enables overlay measurements on smaller targets. These targets can be smaller than the illumination spot and may be surrounded by device product structures on a substrate. In an embodiment, multiple targets can be measured in one radiation capture.

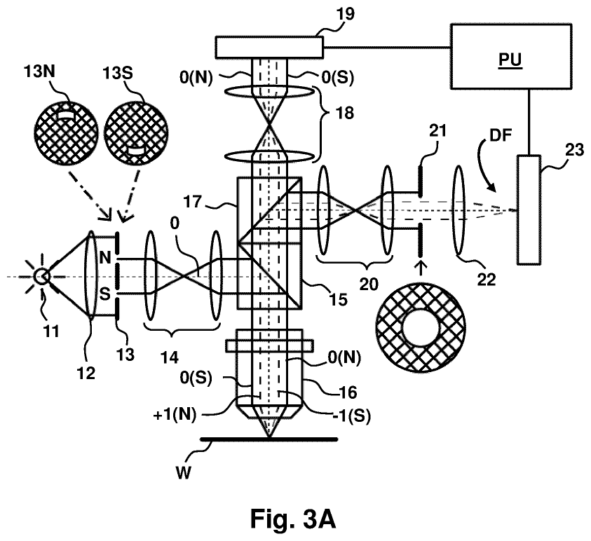

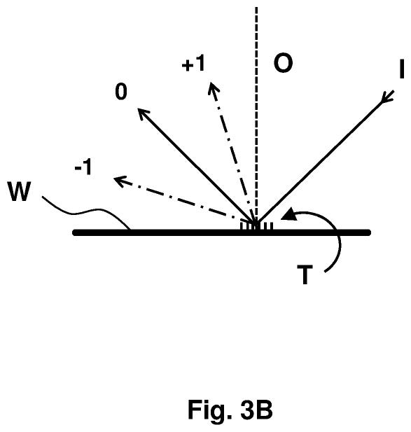

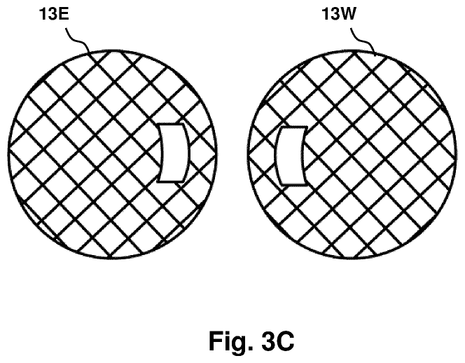

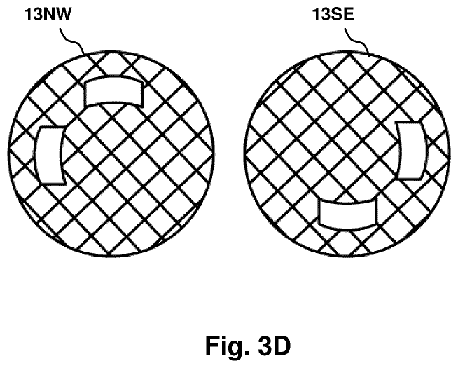

FIG. 3A is schematic diagram of a measurement apparatus for use in measuring targets according to an embodiment using a first pair of illumination apertures providing certain illumination modes. A metrology apparatus suitable for use in embodiments to measure, e.g., overlay is also schematically shown in FIG. 3A. A target T (comprising a periodic structure such as a grating) and diffracted rays are illustrated in more detail in FIG. 3B. The metrology apparatus may be a stand-alone device or incorporated in either the lithographic apparatus LA, e.g., at the measurement station, or the lithographic cell LC. An optical axis, which has several branches throughout the apparatus, is represented by a dotted line O. In this apparatus, radiation emitted by an output 11 (e.g., a source such as a laser or a xenon lamp or an opening connected to a source) is directed onto substrate W via a prism 15 by an optical system comprising lenses 12, 14 and objective lens 16. These lenses are arranged in a double sequence of a 4F arrangement. A different lens arrangement can be used, provided that it still provides a substrate image onto a detector.

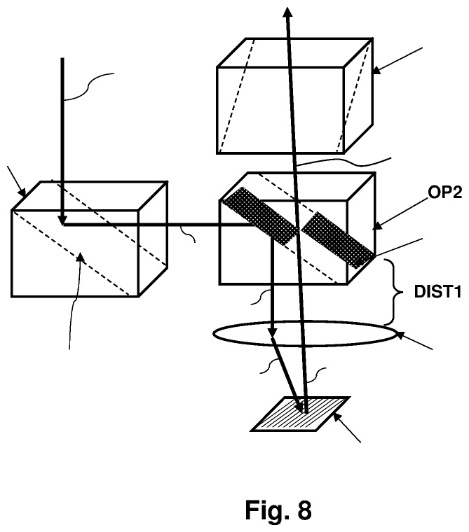

In an embodiment, the prism 15 may be an optical element OP2 (see FIG. 8). The optical element improves the reflection efficiency of the radiation emitted by the output 11 and the transmission efficiency of rays diffracted (e.g., +1(N) and −1(S)) from the substrate W. Advantageously, the optical element OP2 improves the utilization of the radiation emitted by the output 11 by at least three folds. As such, a sensor 19 receives diffraction pattern with high amount of signal related to structure on the substrate, which in turn helps in determining more accurate measurements (e.g., overlay, CD) in less exposure time. On the contrary, if the utilization efficiency is low, the exposure time is high to allow sufficient signal to be captured by sensor 19 to determine measurements accurately. Accordingly, by improving the utilization of radiation by the optical element OP2, faster and more accurate measurements can be obtained from the measurement apparatus or the metrology tool.

In an embodiment, the lens arrangement allows for access of an intermediate pupil-plane for spatial-frequency filtering. Therefore, the angular range at which the radiation is incident on the substrate can be selected by defining a spatial intensity distribution in a plane that presents the spatial spectrum of the substrate plane, here referred to as a (conjugate) pupil plane. In particular, this can be done, for example, by inserting an aperture plate 13 of suitable form between lenses 12 and 14, in a plane which is a back-projected image of the objective lens pupil plane. In the example illustrated, aperture plate 13 has different forms, labeled 13N and 13S, allowing different illumination modes to be selected. The illumination system in the present examples forms an off-axis illumination mode. In the first illumination mode, aperture plate 13N provides off-axis illumination from a direction designated, for the sake of description only, as ‘north’. In a second illumination mode, aperture plate 13S is used to provide similar illumination, but from an opposite direction, labeled ‘south’. Other modes of illumination are possible by using different apertures. The rest of the pupil plane is desirably dark as any unnecessary radiation outside the desired illumination mode may interfere with the desired measurement signals.

FIG. 3B is a schematic detail of a diffraction spectrum of a target for a given direction of illumination. As shown in FIG. 3B, target T is placed with substrate W substantially normal to the optical axis O of objective lens 16. A ray of illumination I impinging on target T from an angle off the axis O gives rise to a zeroth order ray (solid line 0) and two first order rays (dot-chain line +1 and double dot-chain line −1). With an overfilled small target T, these rays are just one of many parallel rays covering the area of the substrate including metrology target T and other features. Since the aperture in plate 13 has a finite width (necessary to admit a useful quantity of radiation), the incident rays I will in fact occupy a range of angles, and the diffracted rays 0 and +1/−1 will be spread out somewhat. According to the point spread function of a small target, each order +1 and −1 will be further spread over a range of angles, not a single ideal ray as shown. Note that the periodic structure pitch and illumination angle can be designed or adjusted so that the first order rays entering the objective lens are closely aligned with the central optical axis. The rays illustrated in FIGS. 3A and 3B are shown somewhat off axis, purely to enable them to be more easily distinguished in the diagram. At least the 0 and +1 orders diffracted by the target on substrate W are collected by objective lens 16 and directed back through prism 15.

Returning to FIG. 3A, both the first and second illumination modes are illustrated, by designating diametrically opposite apertures labeled as north (N) and south (S). When the incident ray I is from the north side of the optical axis, that is when the first illumination mode is applied using aperture plate 13N, the +1 diffracted rays, which are labeled +1(N), enter the objective lens 16. In contrast, when the second illumination mode is applied using aperture plate 13S the −1 diffracted rays (labeled −1(S)) are the ones which enter the lens 16. Thus, in an embodiment, measurement results are obtained by measuring the target twice under certain conditions, e.g., after rotating the target or changing the illumination mode or changing the imaging mode to obtain separately the −1st and the +1st diffraction order intensities. Comparing these intensities for a given target provides a measurement of asymmetry in the target, and asymmetry in the target can be used as an indicator of a parameter of a lithography process, e.g., overlay. In the situation described above, the illumination mode is changed.

A beam splitter 17 divides the diffracted beams into two measurement branches. In a first measurement branch, optical system 18 forms a diffraction spectrum (pupil plane image) of the target on first sensor 19 (e.g. a CCD or CMOS sensor) using the zeroth and first order diffractive beams. Each diffraction order hits a different point on the sensor, so that image processing can compare and contrast orders. The pupil plane image captured by sensor 19 can be used for focusing the metrology apparatus and/or normalizing intensity measurements. The pupil plane image can also be used for other measurement purposes such as reconstruction, as described further hereafter.

In the second measurement branch, optical system 20, 22 forms an image of the target on the substrate W on sensor 23 (e.g. a CCD or CMOS sensor). In the second measurement branch, an aperture stop 21 is provided in a plane that is conjugate to the pupil-plane of the objective lens 16. Aperture stop 21 functions to block the zeroth order diffracted beam so that the image of the target formed on sensor 23 is formed from the −1 or +1 first order beam. Data regarding the images measured by sensors 19 and 23 are output to processor and controller PU, the function of which will depend on the particular type of measurements being performed. Note that the term ‘image’ is used in a broad sense. An image of the periodic structure features (e.g., grating lines) as such will not be formed, if only one of the −1 and +1 orders is present.

The particular forms of aperture plate 13 and stop 21 shown in FIG. 3 are purely examples. In another embodiment, on-axis illumination of the target is used and an aperture stop with an off-axis aperture is used to pass substantially only one first order of diffracted radiation to the sensor. In yet other embodiments, 2nd, 3rd and higher order beams (not shown in FIG. 3) can be used in measurements, instead of or in addition to the first order beams.

In order to make the illumination adaptable to these different types of measurement, the aperture plate 13 may comprise a number of aperture patterns formed around a disc, which rotates to bring a desired pattern into place. Note that aperture plate 13N or 13S are used to measure a periodic structure of a target oriented in one direction (X or Y depending on the set-up). For measurement of an orthogonal periodic structure, rotation of the target through 90° and 270° might be implemented.

FIG. 3C is a schematic illustration of a second pair of illumination apertures providing further illumination modes in using a measurement apparatus for diffraction based overlay measurements.

FIG. 3D is a schematic illustration of a third pair of illumination apertures combining the first and second pairs of apertures providing further illumination modes in using a measurement apparatus for diffraction based overlay measurements.

Different aperture plates are shown in FIGS. 3C and 3D. FIG. 3C illustrates two further types of off-axis illumination mode. In a first illumination mode of FIG. 3C, aperture plate 13E provides off-axis illumination from a direction designated, for the sake of description only, as ‘east’ relative to the ‘north’ previously described. In a second illumination mode of FIG. 3C, aperture plate 13W is used to provide similar illumination, but from an opposite direction, labeled ‘west’. FIG. 3D illustrates two further types of off-axis illumination mode. In a first illumination mode of FIG. 3D, aperture plate 13NW provides off-axis illumination from the directions designated ‘north’ and ‘west’ as previously described. In a second illumination mode, aperture plate 13SE is used to provide similar illumination, but from an opposite direction, labeled ‘south’ and ‘east’ as previously described. The use of these, and numerous other variations and applications of the apparatus are described in, for example, the prior published patent application publications mentioned above.

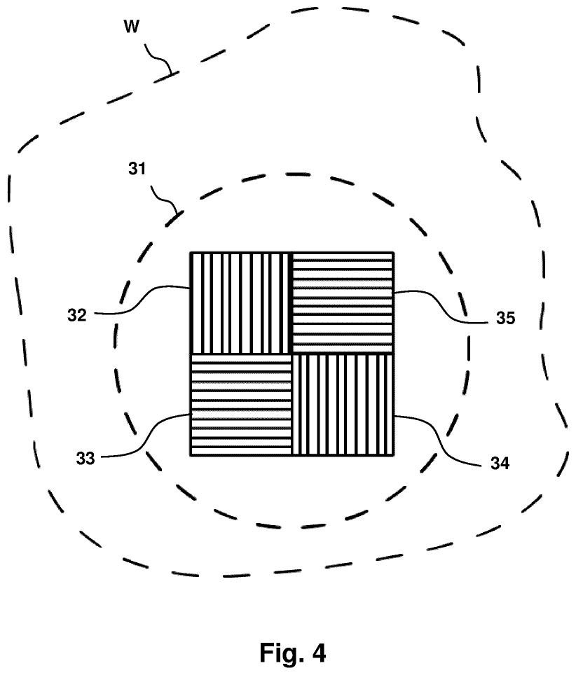

FIG. 4 schematically depicts a form of multiple periodic structure (e.g., multiple grating) target and an outline of a measurement spot on a substrate. An example composite metrology target T is formed on a substrate. The composite target comprises four periodic structures (in this case, gratings) 32, 33, 34, 35 positioned closely together. In an embodiment, the periodic structure layout may be made smaller than the measurement spot (e.g., the periodic structure layout is overfilled). Thus, in an embodiment, the periodic structures are positioned closely together enough so that they all are within a measurement spot 31 formed by the illumination beam of the metrology apparatus. In that case, the four periodic structures thus are all simultaneously illuminated and simultaneously imaged on sensors 19 and 23. In an example dedicated to overlay measurement, periodic structures 32, 33, 34, 35 are themselves composite periodic structures (e.g., composite gratings) formed by overlying periodic structures, e.g., periodic structures are patterned in different layers of the device formed on substrate W and such that at least one periodic structure in one layer overlays at least one periodic structure in a different layer. Such a target may have outer dimensions within 20 μm×20 μm or within 16 μm×16 μm. Further, all the periodic structures are used to measure overlay between a particular pair of layers. To facilitate a target being able to measure more than a single pair of layers, periodic structures 32, 33, 34, 35 may have differently biased overlay offsets in order to facilitate measurement of overlay between different layers in which the different parts of the composite periodic structures are formed. Thus, all the periodic structures for the target on the substrate would be used to measure one pair of layers and all the periodic structures for another same target on the substrate would be used to measure another pair of layers, wherein the different bias facilitates distinguishing between the layer pairs.

Returning to FIG. 4, periodic structures 32, 33, 34, 35 may also differ in their orientation, as shown, so as to diffract incoming radiation in X and Y directions. In one example, periodic structures 32 and 34 are X-direction periodic structures with biases of +d, −d, respectively. Periodic structures 33 and 35 may be Y-direction periodic structures with offsets +d and −d respectively. While four periodic structures are illustrated, another embodiment may include a larger matrix to obtain desired accuracy. For example, a 3×3 array of nine composite periodic structures may have biases −4d, −3d, −2d, −d, 0, +d, +2d, +3d, +4d. Separate images of these periodic structures can be identified in an image captured by sensor 23.

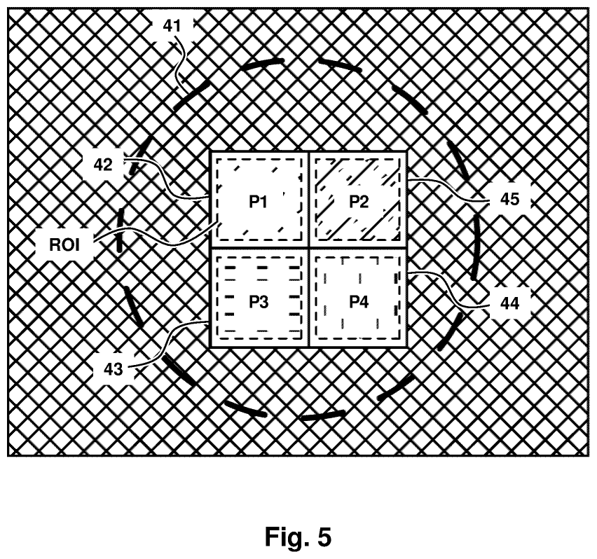

FIG. 5 schematically depicts an image of the target of FIG. 4 obtained in the apparatus of FIG. 3. FIG. 5 shows an example of an image that may be formed on and detected by the sensor 23, using the target of FIG. 4 in the apparatus of FIG. 3, using the aperture plates 13NW or 13SE from FIG. 3D. While the sensor 19 cannot resolve the different individual periodic structures 32 to 35, the sensor 23 can do so. The dark rectangle represents the field of the image on the sensor, within which the illuminated spot 31 on the substrate is imaged into a corresponding circular area 41. Within this, rectangular areas 42-45 represent the images of the periodic structures 32 to 35. The target can be positioned in among device product features, rather than or in addition to in a scribe lane. If the periodic structures are located in device product areas, device features may also be visible in the periphery of this image field. Processor and controller PU processes these images using pattern recognition to identify the separate images 42 to 45 of periodic structures 32 to 35. In this way, the images do not have to be aligned very precisely at a specific location within the sensor frame, which greatly improves throughput of the measuring apparatus as a whole.

Once the separate images of the periodic structures have been identified, the intensities of those individual images can be measured, e.g., by averaging or summing selected pixel intensity values within the identified areas. Intensities and/or other properties of the images can be compared with one another. These results can be combined to measure different parameters of the lithographic process. Overlay performance is an example of such a parameter.

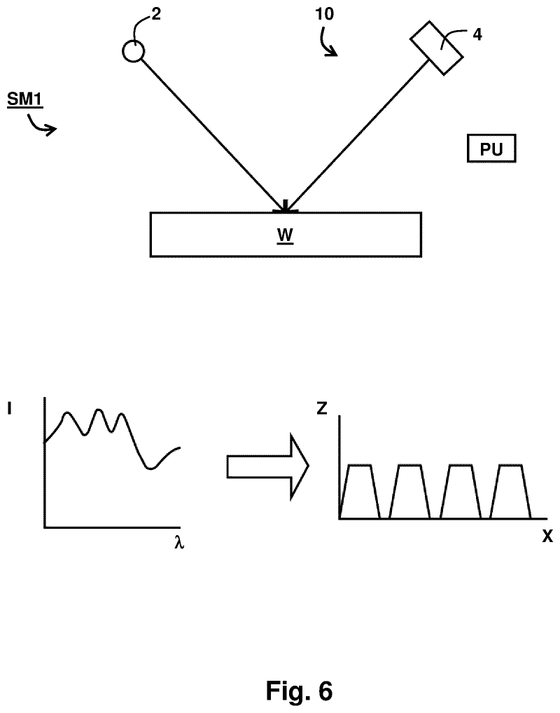

FIG. 6 schematically depicts an example metrology apparatus and metrology technique. In an embodiment, one of the parameters of interest of a patterning process is feature width (e.g., CD). FIG. 6 depicts a highly schematic example metrology apparatus (e.g., a scatterometer) that can enable feature width determination. It comprises a broadband (white light) radiation projector 2 which projects radiation onto a substrate W. The redirected radiation is passed to a spectrometer detector 4, which measures a spectrum 10 (intensity as a function of wavelength) of the specular reflected radiation, as shown, e.g., in the graph in the lower left. From this data, the structure or profile giving rise to the detected spectrum may be reconstructed by processor PU, e.g. by Rigorous Coupled Wave Analysis and non-linear regression or by comparison with a library of simulated spectra as shown at the bottom right of FIG. 6. In general, for the reconstruction the general form of the structure is known and some variables are assumed from knowledge of the process by which the structure was made, leaving only a few variables of the structure to be determined from the measured data. Such a metrology apparatus may be configured as a normal-incidence metrology apparatus or an oblique-incidence metrology apparatus. Moreover, in addition to measurement of a parameter by reconstruction, angle resolved scatterometry is useful in the measurement of asymmetry of features in product and/or resist patterns. A particular application of asymmetry measurement is for the measurement of overlay, where the target comprises one set of periodic features superimposed on another. The concepts of asymmetry measurement in this manner are described, for example, in U.S. patent application publication US2006-066855, which is incorporated herein in its entirety.

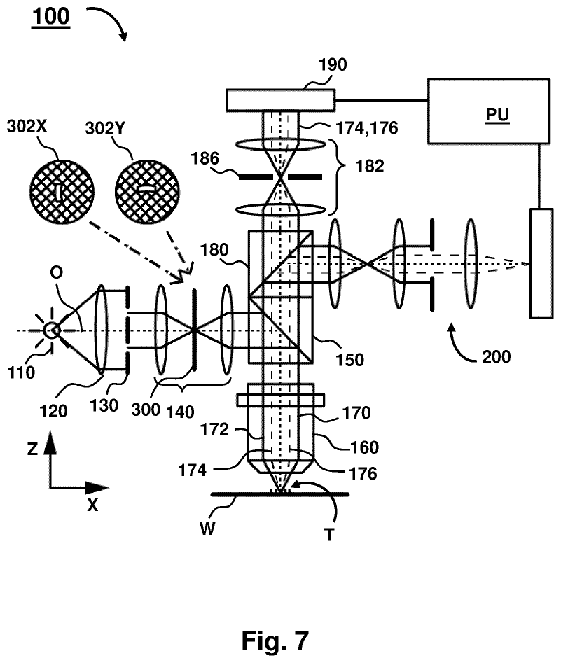

FIG. 7 illustrates an example of a metrology apparatus 100 suitable for use in embodiments of the present disclosure. The principles of operation of this type of metrology apparatus are explained in more detail in the U.S. Patent Application Publication Nos. US 2006-033921 and US 2010-201963, which are incorporated herein in their entireties by reference. An optical axis, which has several branches throughout the apparatus, is represented by a dotted line O. In this apparatus, radiation emitted by source 110 (e.g., a xenon lamp) is directed onto substrate W via by an optical system comprising: lens system 120, aperture plate 130, lens system 140, a partially reflecting surface 150 and objective lens 160. In an embodiment these lens systems 120, 140, 160 are arranged in a double sequence of a 4F arrangement. In an embodiment, the radiation emitted by radiation source 110 is collimated using lens system 120. A different lens arrangement can be used, if desired. The angular range at which the radiation is incident on the substrate can be selected by defining a spatial intensity distribution in a plane that presents the spatial spectrum of the substrate plane. In particular, this can be done by inserting an aperture plate 130 of suitable form between lenses 120 and 140, in a plane which is a back-projected image of the objective lens pupil plane. Different intensity distributions (e.g., annular, dipole, etc.) are possible by using different apertures. The angular distribution of illumination in radial and peripheral directions, as well as properties such as wavelength, polarization and/or coherency of the radiation, can all be adjusted to obtain desired results. For example, one or more interference filters 130 can be provided between source 110 and partially reflecting surface 150 to select a wavelength of interest in the range of, say, 400-900 nm or even lower, such as 200-300 nm. The interference filter may be tunable rather than comprising a set of different filters. A grating could be used instead of an interference filter. In an embodiment, one or more polarizers 170 can be provided between source 110 and partially reflecting surface 150 to select a polarization of interest. The polarizer may be tunable rather than comprising a set of different polarizers.

As shown in FIG. 7, the target T is placed with substrate W normal to the optical axis O of objective lens 160. Thus, radiation from source 110 is reflected by partially reflecting surface 150 and focused into an illumination spot S on target T on substrate W via objective lens 160. In an embodiment, objective lens 160 has a high numerical aperture (NA), desirably at least 0.9 or at least 0.95. An immersion metrology apparatus (using a relatively high refractive index fluid such as water) may even have a numerical aperture over 1.

Rays of illumination 170, 172 focused to the illumination spot from angles off the axis O gives rise to diffracted rays 174, 176. It should be remembered that these rays are just one of many parallel rays covering an area of the substrate including target T. Each element within the illumination spot is within the field of view of the metrology apparatus. Since the aperture in plate 130 has a finite width (necessary to admit a useful quantity of radiation), the incident rays 170, 172 will in fact occupy a range of angles, and the diffracted rays 174, 176 will be spread out somewhat. According to the point spread function of a small target, each diffraction order will be further spread over a range of angles, not a single ideal ray as shown.

At least the 0^{th} order diffracted by the target on substrate W is collected by objective lens 160 and directed back through partially reflecting surface 150. An optical element 180 provides at least part of the diffracted beams to optical system 182 which forms a diffraction spectrum (pupil plane image) of the target T on sensor 190 (e.g. a CCD or CMOS sensor) using the zeroth and/or first order diffractive beams. In an embodiment, an aperture 186 is provided to filter out certain diffraction orders so that a particular diffraction order is provided to the sensor 190. In an embodiment, the aperture 186 allows substantially or primarily only zeroth order radiation to reach the sensor 190. In an embodiment, the sensor 190 may be a two-dimensional detector so that a two-dimensional angular scatter spectrum of a substrate target T can be measured. The sensor 190 may be, for example, an array of CCD or CMOS sensors, and may use an integration time of, for example, 40 milliseconds per frame. The sensor 190 may be used to measure the intensity of redirected radiation at a single wavelength (or narrow wavelength range), the intensity separately at multiple wavelengths or integrated over a wavelength range. Furthermore, the sensor may be used to separately measure the intensity of radiation with transverse magnetic- and/or transverse electric-polarization and/or the phase difference between transverse magnetic- and transverse electric-polarized radiation.

Optionally, optical element 180 provides at least part of the diffracted beams to measurement branch 200 to form an image of the target on the substrate Won a sensor 230 (e.g. a CCD or CMOS sensor). The measurement branch 200 can be used for various auxiliary functions such as focusing the metrology apparatus (e.g., enabling the substrate W to be in focus with the objective 160), and/or for dark field imaging of the type mentioned in the introduction.

In order to provide a customized field of view for different sizes and shapes of grating, an adjustable field stop 300 is provided within the lens system 140 on the path from source 110 to the objective lens 160. The field stop 300 contains an aperture 302 and is located in a plane conjugate with the plane of the target T, so that the illumination spot becomes an image of the aperture 302. The image may be scaled according to a magnification factor, or the aperture and illumination spot may be in 1:1 size relation. In order to make the illumination adaptable to different types of measurement, the aperture plate 300 may comprise a number of aperture patterns formed around a disc, which rotates to bring a desired pattern into place. Alternatively or in addition, a set of plates 300 could be provided and swapped, to achieve the same effect. Additionally or alternatively, a programmable aperture device such as a deformable mirror array or transmissive spatial light modulator can be used also.

Typically, a target will be aligned with its periodic structure features running either parallel to the Y axis or parallel to the X axis. With regard to its diffractive behavior, a periodic structure with features extending in a direction parallel to the Y axis has periodicity in the X direction, while the periodic structure with features extending in a direction parallel to the X axis has periodicity in the Y direction. In order to measure the performance in both directions, both types of features are generally provided. While for simplicity there will be reference to lines and spaces, the periodic structure need not be formed of lines and space. Moreover, each line and/or space between lines may be a structure formed of smaller sub-structures. Further, the periodic structure may be formed with periodicity in two dimensions at once, for example where the periodic structure comprises posts and/or via holes.

In order to monitor the lithographic process, it is necessary to measure parameters of the patterned substrate, for example the overlay error between successive layers formed in or on it. There are various techniques for making measurements of the microscopic structures formed in lithographic processes, including the use of scanning electron microscopes and various specialized tools. One form of specialized inspection tool is a scatterometer in which a beam of radiation is directed onto a target on the surface of the substrate and properties of the scattered or reflected beam are measured. By comparing the properties of the beam before and after it has been reflected or scattered by the substrate, the properties of the substrate can be determined. This can be done, for example, by comparing the reflected beam with data stored in a library of known measurements associated with known substrate properties. Two main types of scatterometer are known. Spectroscopic scatterometers direct a broadband radiation beam onto the substrate and measure the spectrum (intensity as a function of wavelength) of the radiation scattered into a particular narrow angular range. Angularly resolved scatterometers use a monochromatic radiation beam and measure the intensity of the scattered radiation as a function of angle.

Devices are built up layer by layer and overlay is a measure of a lithographic apparatus' ability to print these layers accurately on top of each other. Successive layers or multiple processes on the same layer must be accurately aligned to the previous layer, otherwise electrical contact between structures will be poor and the resulting devices will not perform to specification. Overlay is a measure of the accuracy of this alignment. Good overlay improves device yield and enables smaller product patterns to be printed. The overlay error between successive layers formed in or on the patterned substrate is controlled by various parts of the exposure apparatus (of the lithographic apparatus). In an embodiment, the overlay is measured by a metrology tool herein, and adjustments are made to lithographic apparatus (e.g., the alignment system that is responsible for the alignment of the radiation onto the correct portions of the substrate) so that to obtain desired overlay performance.

Existing optical elements used in a metrology tool includes a 50/50 beam splitter to combine different illumination and detection beam paths together. The existing 50/50 beam splitter includes a coating that performs the function of reflectivity and transmissivity required to combine the different radiation paths. However, the radiation goes through a double pass via the 50/50 beam splitter, as such only approximately 25% of the illumination beam is utilized and goes to a sensor such as a dark field camera, while remaining of the illumination beam is wasted. A low efficiency of beam utilization affects measurement throughput. As such, more time may be required for measurements thereby reducing throughput. An improved optical element to increase the beam utilization for measurements (e.g., overlay measurements) and thereby increase throughput of a metrology tool is desired. As discussed herein, measurements may be performed during a semiconductor manufacturing and based on the measurements adjustment may be made to a lithographic apparatus to improve the yield. As such, faster and more accurate measurements also improves yield and throughput of the semiconductor manufacturing process.

FIG. 8 illustrates an optical element OP2 having portions with high reflectivity and portions with high transmissivity. In an embodiment, the optical element OP2 includes two quadrants with high reflectivity and two quadrants with high transmissivity that enables approximately three times (3×) more beam utilization efficiency without significantly changing an optical architecture of an existing metrology tool. In an embodiment, the optical element OP2 is placed close to an objective entrance pupil EP. Small adjustment may be made to the illumination mode selector (e.g., that creates different illumination modes) to avoid vignetting without impacting application space.

In an embodiment, a source (e.g., as shown in FIGS. 3A and 7) emits radiation rays IR1 that may be reflect from a reflector surface RS1 placed diagonally along a first optical element OP1 towards a second optical element OP2. The second optical element OP2 (also referred as the optical element OP2) receives the reflected ray IR2. The optical element OP2 is configured to perform two functions including reflecting the ray IR2 toward the substrate W, and transmits the ray RE1 diffracted from the substrate W. In an embodiment, the ray IR2 may be reflected at an angle to generate ray IR3, which is incident on the substrate W. In an embodiment, the diffracted ray RE1 (e.g., first order diffractions) is transmitted by the optical element OP2 toward a third optical element OP2. In an embodiment, the third optical element OP3 may be similar to optical elements 18 (in FIG. 3A) or 180 (in FIG. 7).

The optical element OP2 is configured to partially reflect the beam along the illumination path (e.g., including rays IR1 and IR2) in a first direction (e.g., towards the substrate W, or other desired elements in a tool), and to transmit the beam along the detection path (e.g., including rays RE1 and RE2) in a second direction (e.g., towards a camera, a signal sensor, or other desired elements in a tool). In an embodiment, the transmitted beam RE1 comprises 1^{st} order diffractions caused by an illuminated portion of an object. For example, the 1^{st} order diffraction caused by gratings on the substrate W whose overlay is to be measured. In an embodiment, the optical element OP2 may be a polarized beam splitter or a non-polarizing beam splitter. In an embodiment, the optical element OP2 may be a mirror.

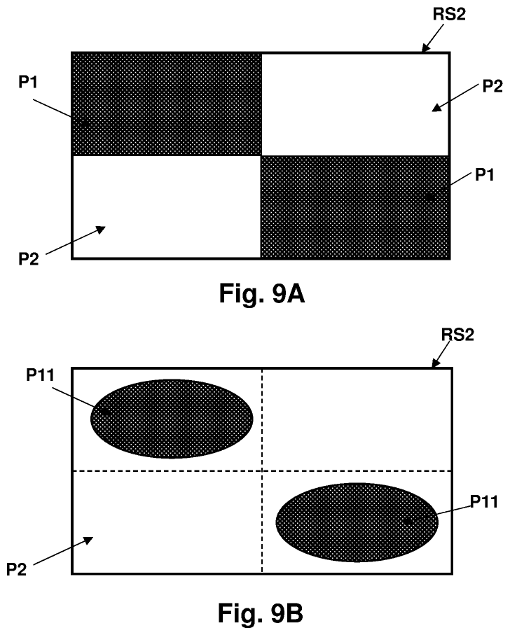

Referring to FIGS. 8 and 9A-9B, the optical element OP2 include a first portion P1 (or P11) configured to reflect the illumination beam received from the illumination source towards the substrate. The optical element OP2 also includes a second portion P2 configured to transmit beam reflected from the substrate or the desired location in the optical tool. In the FIGS. 8 and 9A-9B, the shaded portions refer to first portion and the blank/white portions refer to the second portion. In an embodiment, the first portion P1 has a higher coefficient of reflectivity than the second portion P2, and the second portion P2 has higher coefficient of transmissivity than the first portion P1. In the discussion herein, the first portion and second portion are referred as P1 and P2 for convenience, but not the scope is not limited to such portions. Alternatively, or in addition, the first and the second portions may be P11 and P2, respectively.

In an embodiment, the first portion P1 corresponds to regions of the optical element that receive the beam from the illumination source and further direct the beam toward the substrate to be measured. In an embodiment, the second portion P2 corresponds to regions of the optical element that receive the beam reflected from the substrate. In an embodiment, the second portion P2 corresponds to regions of the optical element that receive first order diffractions of the beam reflected from the substrate causing the first order diffractions to pass through the optical element. In an embodiment, the first order diffractions include sufficient information related to structures on the substrate. In an embodiment, higher order diffraction may not be transmitted or may get rejected by the optical element OP2. In an embodiment, the higher order diffraction may be avoided by selecting the ratio between illumination wavelengths and grating pitch distance of the substrate. In an embodiment, the zeroth order may be used for calibration and setting up the metrology system.

Referring to FIGS. 8 and 9A, the first portion P1 comprises a first quadrant region and a third quadrant region of the surface RS2 of the optical element OP2, and the second portion P2 comprises a second quadrant region and a fourth quadrant region of the surface RS2 of the optical element OP2. However, the present disclosure is not limited to particular quadrants or shapes. For example, the first portion may be P11 and the second portion may be P2, as shown in FIG. 9B. In FIG. 9B, the first portions P11 may be oval shaped partially filling respective quadrants and located in opposite quadrants. According to the present disclosure, the transition zone between P1 and P2 portions or coatings is desired to be as small as possible to maximize the illumination pupil fill, otherwise there will be throughput loss. So, the optical element also requires accurate alignment such that the illumination light is not clipped by the transition zone.

In an embodiment, the first portion P1 may correspond to a shape of the illumination pupil. For example, the illumination pupil shape may be controlled by an aperture configured to shape the illumination pupil, where only a portion of the illumination pupil emits radiation. FIGS. 3C and 3D illustrates example aperture shapes.

In an embodiment, the first portion P1 may have the coefficient of reflectivity between 51%-100%. In a preferred embodiment, the coefficient of reflectivity may be greater than 90%. In an embodiment, the first portion P1 comprises a reflective coating formed on a glass substrate where the beam from the illumination source is incident on the optical element. In an embodiment, the second portion P2 may have the coefficient of transmissivity between 51%-100%. In a preferred embodiment, the coefficient of transmissivity may be greater than 90%. In an embodiment, the second portion P2 comprises a transparent glass material. In an example, when the first portion P1 has a reflectivity of 90% and transmissivity of 95%, the utilization of the beam will be approximately 0.9*0.95 i.e., 0.855 Or 85%, which is substantially higher than 25% of existing optical elements.

In an embodiment, the reflective coating may be a metallic coating, dielectric coating, or a total internal reflection surface. In an embodiment, the reflective coating may be formed using beam splitting coating approach or other known coating approaches. An example of the glass substrate may be a fused-quartz substrate, an acrylic substrate, dielectric mirror, and any other glass substrate for optical use. In an embodiment, the reflective coating may be applied at the first portion P1 of a low iron glass to minimize the tint and have an anti-reflective coating on the back to eliminate a double reflection. In an embodiment, the first portion P1 comprises one or more mirrors positioned to receive the beam from the illumination source and reflect the beam to the substrate or the desired location. The first portion may be a high reflective coating with a total internal reflection surface or a mirror coating with no transmission.

In an embodiment, the second portion P2 may be formed of a high transmission coating on a transparent glass material, no coating but two contacted/cemented transparent glass materials, holes (e.g., oval shaped holes in place of P11) for pure transmission of beam, or a combination thereof.

In an embodiment, the optical element OP2 may be formed as a unitary component, or as a cube with the optical element sandwiched between two halves of the cube along a diagonal. For example, a glass plate coated with the first portion P1 with high reflectivity and the second portion P2 with high transmissivity may be placed along a diagonal of a glass cube. The glass cube be may any transparent material formed of two parts e.g., a first half of the cube with a face the diagonal and a second half of the cube with the face of the diagonal. The glass plate can be plated between the two halves along the diagonal thereby forming the optical element. In an embodiment, the optical element may be formed in different shapes and sizes depending on the application and space available for installing the optical element.

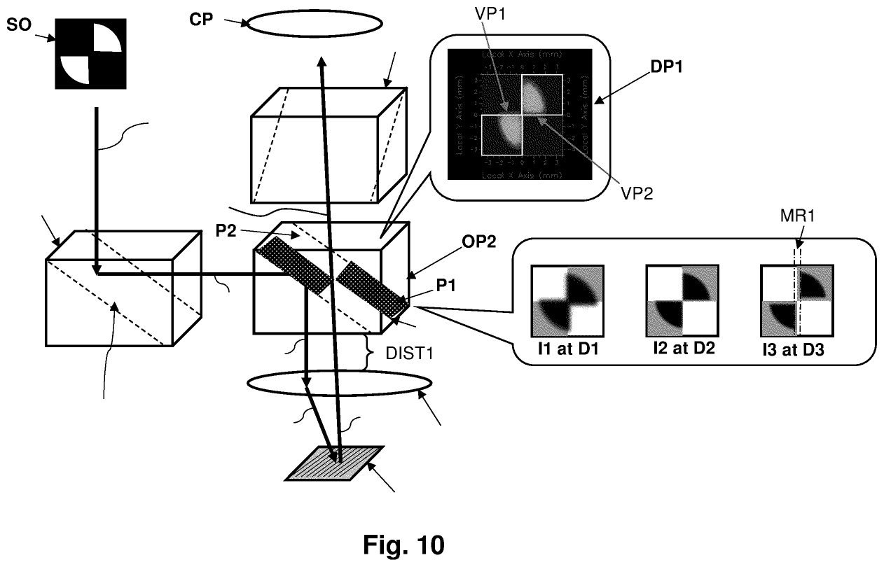

In an embodiment, the optical element OP2 is positioned at a distance within a specified range DIST1 (e.g., see FIGS. 8 and 10) from an entrance pupil plane EP of an objective lens. In an embodiment, the specified range may be anywhere between an entrance pupil and a field conjugate plane. In an embodiment, the specified range DIST1 may be as close as possible to the entrance pupil unless there is an obstruction therebetween (e.g., due to some mechanical components).

In an embodiment, the specified range DIST1 may be specified between the coatings of the first portion and the entrance pupil EP (or conjugated planes) within the metrology tool. For example, in FIG. 8, when the surface RS2 of the optical element OP2 is disposed diagonally, the farthest point of the first portion P1 from the entrance pupil EP may be within the desired range DIST1, and the closest point of the first portion P1 may be within desired range DIST1. In an embodiment, the range DIST1 may be from 0 (right at a pupil conjugated plane) to anywhere between pupil and field conjugate planes. In an example metrology tool, the distance DIST1 may be between 0 to 14.5 mm from the entrance pupil EP of an objective lens that directs the radiation to the substrate W. In an embodiment, the distance may depend on the focal length of the lenses. In an example tool, a focal length that focus the illumination beam at the entrance Pupil (EP) may be 100 mm, and the optical element is placed at 14.2 mm to the entrance pupil EP because it may be a shortest distance available, before the components start to interfere each other due to space constraints.

In an embodiment, the distance is maintained in the desired range DIST1 between the first portion P1 and the entrance pupil EP to prevent clipping or vignetting of diffracted rays RE1. In other words, the specified range DIST1 from the entrance pupil plane is a distance at which the optical element OP2 captures a diffraction pattern caused by the beam diffracted from the substrate W without vignetting (e.g., blurring or cutting) of edge portions of the diffraction pattern (e.g., as illustrated in FIG. 10). In the existing 50-50 beam splitter, it is a simple uniform beam splitting coating and no “clipping/vignetting” happens at this coating, so its location doesn't matter other than space constraints. However, for the first portion (e.g., quadrant coatings), since it may act like an aperture in the optical system, where you clip the diffracted beam may become important.

FIG. 10 illustrates example effect of varying a distance between the optical element OP2 and the entrance pupil EP for a given source pupil shape and quadrant based first portions P1, according to an embodiment. In the present example, a source SO having illumination pupil shaped as shown, where the white portion indicates radiation emitting portions. The illumination beam travels as IR1 and IR2, as discussed earlier, and received by the optical element OP2. The first portion of the optical element OP2 reflects more than 80% of the illumination beam IR2 toward the substrate W. The reflected beam IR3 passes through the entrance pupil EP of the objective lens and the beam IR4 (e.g., angled beam) is incident on the substrate W having gratings or other structures. The beam IR4 gets diffracted due to the grating, causing the diffracted beam RE1 to have a diffraction pattern. The diffraction pattern may be illustrated as a pixelated image, each pixel having values corresponding to the diffraction effect (e.g., including 1^{st} order diffractions) caused by the grating. The diffraction beam RE1 also passes through the entrance pupil EP.

In FIG. 10, examples of different images I1, I2, and I3 generated by varying distance DIST1 between the optical element OP2, and the entrance pupil EP are illustrated. The image I1, I2, I3 shown in FIG. 10 are the images at the optical element plane RS2 where coating is applied, for example a quad coating plane. An exemplary diffraction pattern DPi (dark portions) generated when the optical element is placed at the distance D1 is also shown. For example, when the optical element OP2 is at a first distance D1 (having value outside the desired range DIST1), the first diffraction pattern DPi is observed. It can be seen that at distance D1, portions (e.g., VP1 and VP2) of the diffraction pattern DPi are outside the third and fourth quadrant which indicates beam corresponding to portions VP1 and VP2 will not be transmitted through the second portion of the optical element OP2, also referred as vignetting. The image I1 shows that at the quadrant boundaries, edge portions (dark) are blocked by the first portion (e.g., shaded portion P1) of the optical element OP2. Due to such blocking at the edges, vignetting is observed in the diffraction pattern DPi at the quadrant edge portions VP1 and VP2.

On the other hand, when the optical element OP2 is positioned at a distance D2 that is within the desired range DIST1, such vignetting may be reduced or eliminated. For example, as shown at the entrance pupil EP, for distance D2, the image I2 the dark (black) portion is not cut at the quadrant boundaries and correspond to the bright (white) portions of the illumination SO. In other words, the bright (white) portions of SO and the corresponding dark (black) portions observed at the entrance pupil EP are within the second portion (e.g., white portion P2) of the optical element OP2. Hence, beam corresponding to the source is transmitted after diffraction through the second portion (e.g., white portion P2) of the optical element OP2

In an embodiment, when the optical element OP2 is positioned at a distance D3 (different from D2) which is also within the desired range DIST1. An advantage of placing the optical element at distance D3 is availability of a margin M1 to prevent vignetting. Such margin can further be advantageous, as there will be room to make minor adjustments to one or more components of the metrology tool improve measurements, such as improve overlay or CD. In the FIG. 10, an image at the distance D3 shows the margin M1 with respect to quadrant boundaries. As shown, the dark (black) portions are slightly inside the respective quadrants (e.g., 2^{nd} and 4^{th} quadrant corresponding to the second portion P2). Thus, in an embodiment, a distance D3 may be desired.

The optical element OP2 may be implement in different applications such as a metrology tool configured to measure physical characteristics of a patterned substrate, or as a part of measurement system in a lithographic apparatus. For example, as shown in FIG. 3A, the optical element 15 may be the optical element OP2 configured according to the present disclosure. In another example, as shown in FIG. 7, the optical element 150 may be the optical element OP2 configured according to the present disclosure. The locations of the optical elements OP2 in the metrology tool are only exemplary. A person of ordinary skill in the art may place one or more optical element OP2 at different locations that satisfy the configuration set up according to the present disclosure. For example, an optical element OP2 may be placed close to an entrance pupil and another one may be placed close to a conjugate plane (e.g., CP in FIG. 10) at which an image similar to the image at the entrance pupil may be generated. In an embodiment, the optical element is located within a specified distance from an entrance pupil of a first objective lens near the substrate, or within the specified distance from a conjugate plane of a second objective lens located away from the substrate along a detection path. For example, a second optical element OP2 may be placed at the conjugate plane (e.g., CP in FIG. 10) of a micro diffraction-based overlay branch that receives the diffraction pattern of the substrate.

Also, in an embodiment, the optical element may be part of an optical measurement tool used in the lithographic cells set up as shown in FIG. 2A. The present disclosure is not limited to a particular metrology tool or lithographic apparatus.

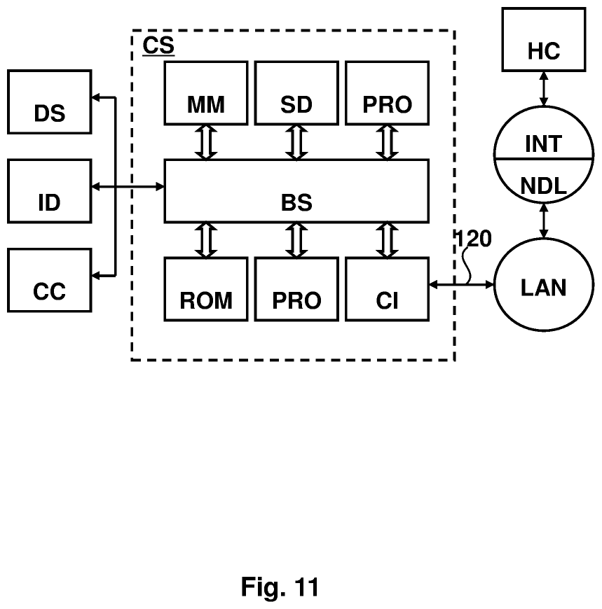

In an embodiment, a tool (e.g., see FIGS. 3A and 7) comprises a sensor for receiving the beam transmitted through the second portion P2 of the optical element OP2. In an embodiment, the tool may include a processor configured to measure physical characteristics of a patterned substrate based on a diffraction pattern detected by the sensor. For example, the physical characteristics is at least one of a critical dimension of a pattern on the patterned substrate, or overlay between patterns on a first layer and a second layer of the patterned substrate. In an embodiment, the processor may be included in a computer system (e.g., see FIG. 11) and configured to receive sensor data from the tools herein. In an embodiment, the processor may be integrated into the tool itself. The present disclosure is not limited to a particular location of the processor.

Accordingly, in an embodiment, a system may be configured as discussed herein to include an illumination source, the optical element OP2, a sensor configured to receive diffraction pattern caused by the patterned substrate, and a processor configured to receive signal comprising the diffraction pattern from the sensor, and determine overlay associated with the patterned substrate by analyzing the signal comprising the diffraction pattern.

FIG. 11 is a block diagram of an example computer system CS, according to an embodiment. The computer system CS may be used for controlling the lithographic apparatus in FIG. 1, determining whether the overlay measurement breaches on an overlay threshold value in the step P1010, or calculating the overlay error as discussed in the step P1008-3. Computer system CS includes a bus BS or other communication mechanism for communicating information, and a processor PRO (or multiple processor) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions to be executed by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions contained in main memory MM causes processor PRO to perform the process steps described herein. One or more processors in a multi-processing arrangement may also be employed to execute the sequences of instructions contained in main memory MM. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the features described herein. Transitory computer-readable media can include a carrier wave or other propagating electromagnetic signal.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated service digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) both use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

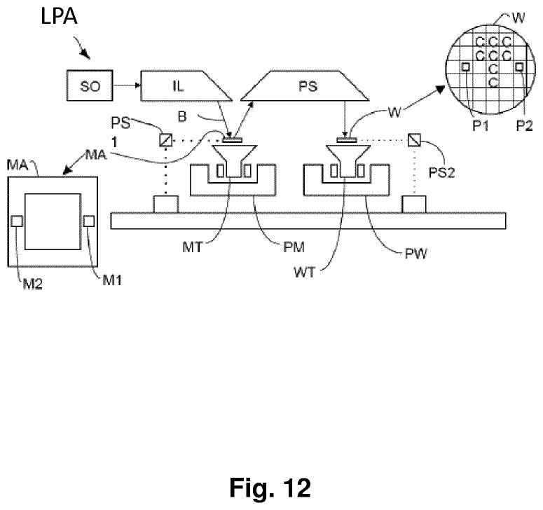

FIG. 12 is a schematic diagram of another lithographic projection apparatus (LPA), according to an embodiment.

LPA can include source collector module SO, illumination system (illuminator) IL configured to condition a radiation beam B (e.g. EUV radiation), support structure MT, substrate table WT, and projection system PS.

Support structure (e.g. a patterning device table) MT can be constructed to support a patterning device (e.g. a mask or a reticle) MA and connected to a first positioner PM configured to accurately position the patterning device;

Substrate table (e.g. a wafer table) WT can be constructed to hold a substrate (e.g. a resist coated wafer) W and connected to a second positioner PW configured to accurately position the substrate.

Projection system (e.g. a reflective projection system) PS can be configured to project a pattern imparted to the radiation beam B by patterning device MA onto a target portion C (e.g. comprising one or more dies) of the substrate W.

As here depicted, LPA can be of a reflective type (e.g. employing a reflective patterning device). It is to be noted that because most materials are absorptive within the EUV wavelength range, the patterning device may have multilayer reflectors comprising, for example, a multi-stack of molybdenum and silicon. In one example, the multi-stack reflector has a 40 layer pairs of molybdenum and silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Illuminator IL can receive an extreme ultra violet radiation beam from source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. Source collector module SO may be part of an EUV radiation system including a laser, not shown in FIG. 11, for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser may not be considered to form part of the lithographic apparatus and the radiation beam can be passed from the laser to the source collector module with the aid of a beam delivery system comprising, for example, suitable directing mirrors and/or a beam expander. In other cases, the source may be an integral part of the source collector module, for example when the source is a discharge produced plasma EUV generator, often termed as a DPP source.

Illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B can be incident on the patterning device (e.g., mask) MA, which is held on the support structure (e.g., patterning device table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder or capacitive sensor), the substrate table WT can be moved accurately, e.g. so as to position different target portions C in the path of radiation beam B. Similarly, the first positioner PM and another position sensor PS1 can be used to accurately position the patterning device (e.g. mask) MA with respect to the path of the radiation beam B. Patterning device (e.g. mask) MA and substrate W may be aligned using patterning device alignment marks M1, M2 and substrate alignment marks P1, P2.

The depicted apparatus LPA could be used in at least one of the following modes, step mode, scan mode, and stationary mode.

In step mode, the support structure (e.g. patterning device table) MT and the substrate table WT are kept essentially stationary, while an entire pattern imparted to the radiation beam is projected onto a target portion C at one time (e.g. a single static exposure). The substrate table WT is then shifted in the X and/or Y direction so that a different target portion C can be exposed.

In scan mode, the support structure (e.g. patterning device table) MT and the substrate table WT are scanned synchronously while a pattern imparted to the radiation beam is projected onto target portion C (e.g. a single dynamic exposure). The velocity and direction of substrate table WT relative to the support structure (e.g. patterning device table) MT may be determined by the (de-)magnification and image reversal characteristics of the projection system PS.

In stationary mode, the support structure (e.g. patterning device table) MT is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

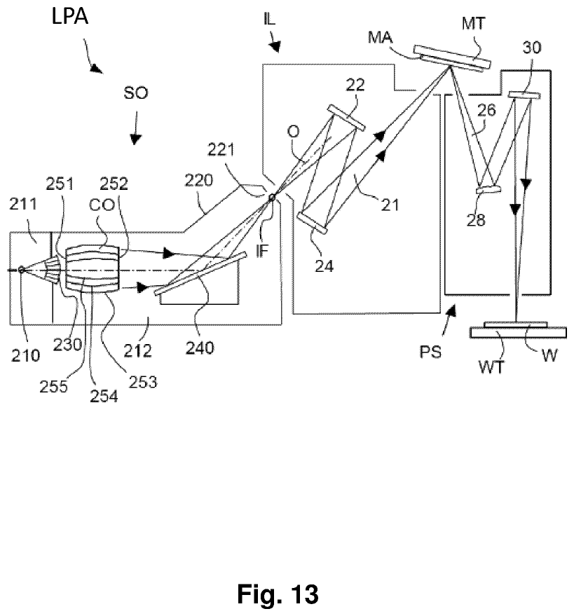

FIG. 13 is a detailed view of the lithographic projection apparatus, according to an embodiment.

As shown, LPA can include the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure, as known in the art.

The collector chamber 211 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF along the optical axis indicated by the dot-dashed line ‘O’. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in illumination optics unit IL and projection system PS. The grating spectral filter 240 may optionally be present, depending upon the type of lithographic apparatus. Further, there may be more mirrors present than those shown in the figures, for example there may be 1-6 additional reflective elements present in the projection system PS than shown in FIG. 12.

Collector optic CO, as illustrated in FIG. 12, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type may be used in combination with a discharge produced plasma source, often called a DPP source.

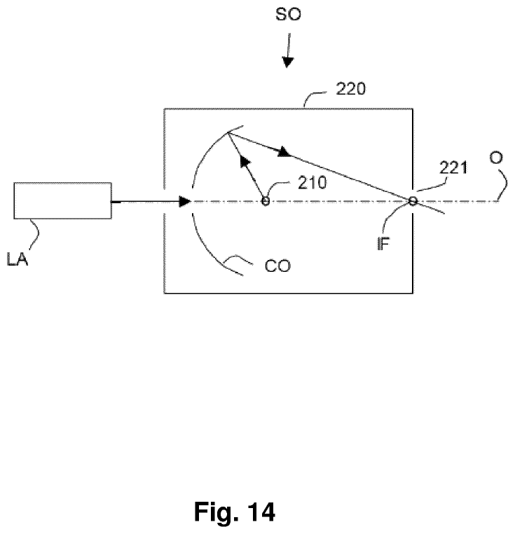

FIG. 14 is a detailed view of source collector module SO of lithographic projection apparatus LPA, according to an embodiment.

Source collector module SO may be part of an LPA radiation system. A laser LA can be arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

The embodiments may further be described using the following clauses:

1. An optical tool comprising:
an illumination source;
an objective lens configured to direct light from the illumination source to a substrate or a desired location in the optical tool; and
an optical element comprising:
   a first portion configured to reflect the light received from the illumination source towards the substrate, and
   a second portion configured to transmit the light reflected from the substrate or the desired location in the optical tool, the first portion having higher coefficient of reflectivity than the second portion, and the second portion having higher coefficient of transmissivity than the first portion.

2. The optical tool of clause 1, wherein the optical element is positioned at a distance within a specified range from a entrance pupil or a conjugate pupil of the objective lens, wherein the specified range is between the entrance pupil and a conjugate plane, and the distance is measured between a point on the first portion, and the entrance pupil or the conjugate pupil.

3. The optical tool of clause 2, wherein the specified range from the entrance pupil or a conjugate pupil is a range at which the optical element captures a diffraction pattern caused by the light directed from the first portion onto the substrate and diffracted from the substrate without causing vignetting.

4. The optical tool of clause 1, wherein the first portion has the coefficient of reflectivity between 51% to 100%.

5. The optical tool of any of clauses 1-4, wherein the first portion comprises a reflective coating formed on a glass substrate where the light from the illumination source is incident on the optical element.

6. The optical tool of any of clauses 1-4, wherein the first portion comprises one or more mirrors positioned to receive the light from the illumination source and reflect the light to the substrate or the desired location.

7. The optical tool of any of clauses 1-6, wherein the second portion has the coefficient of transmissivity between 51% to 100%.

8. The optical tool of any of clauses 1-7, wherein the second portion comprises a transparent glass material, a high transmission coating on a transparent glass material, no coating with two transparent glass material contacted together, or holes for pure transmission.

9. The optical tool of any of clauses 1-8, wherein the first portion corresponds to regions of the optical element that receive the light from the illumination source and further direct the light toward the substrate to be measured.

10. The optical tool of any of clauses 1-9, wherein the second portion corresponds to regions of the optical element that receive the light reflected from the substrate.

11. The optical tool of clause 10, wherein the second portion corresponds to regions of the optical element that receive first order diffractions of the light reflected from the substrate causing the first order diffractions to pass through the optical element.

12. The optical tool of any of clauses 1-11, wherein the first portion comprises a first quadrant region and a third quadrant region of the optical element; and the second portion comprises a second quadrant region and a fourth quadrant region of the optical element.

13. The optical tool of any of clauses 1-12, further comprises:
a sensor for receiving the light transmitted through the second portion of the optical element.

14. The optical tool of clause 13, further comprises:
a processor configured to measure physical characteristics of a patterned substrate based on a diffraction pattern detected by the sensor.

15. The optical tool of clause 14, wherein the physical characteristics is at least one of a critical dimension of a pattern on the patterned substrate, or overlay between patterns on a first layer and a second layer of the patterned substrate.

16. The optical tool of any of clauses 1-15, wherein the optical element is located within a specified distance from a entrance pupil or a conjugate pupil of a first objective lens near the substrate, or within the specified distance from a conjugate pupil of a second objective lens located away from the substrate.

17. The optical tool of any of clauses 1-16, wherein the optical element is a non-polarizing beam splitter or a polarizing beam splitter.

18. A system for measuring overlay of patterned substrates comprising:
an illumination source to illuminate a patterned substrate;
an optical element comprising a first portion configured to reflect light received from the illumination source, and a second portion configured to transmit the light reflected from the patterned substrate, the first portion having higher coefficient of reflectivity than the second portion, the second portion having higher coefficient of transmissivity than the first portion;
a sensor configured to receive diffraction pattern caused by the patterned substrate; and
a processor configured to receive signal comprising the diffraction pattern from the sensor, and determine overlay associated with the patterned substrate by analyzing the signal comprising the diffraction pattern.

19. The system of clause 18, wherein the optical element is positioned at a distance within a specified range from a entrance pupil or a conjugate pupil of the objective lens, wherein the specified range is between the entrance pupil and a conjugate plane, and the distance is measured between a point on the first portion, and the entrance pupil or the conjugate pupil.

20. The system of clause 18, wherein the specified range from the entrance pupil or a conjugate pupil is a range at which the optical element captures a diffraction pattern caused by the light directed from the first portion onto the substrate and diffracted from the substrate without causing vignetting.

21. The system of clause 18, wherein the first portion has the coefficient of reflectivity between 51% to 100%.

22. The system of any of clauses 18-21, wherein the first portion comprises a reflective coating formed on a glass substrate where the light from the illumination source is incident on the optical element.

23. The system of any of clauses 18-21, wherein the first portion comprises one or more mirrors positioned to receive the light from the illumination source and reflect the light to the substrate or the desired location.

24. The system of any of clauses 18-23, wherein the second portion has the coefficient of transmissivity between 51% to 100%.

25. The system of any of clauses 18-24, wherein the second portion comprises a transparent glass material, a high transmission coating on a transparent glass material, no coating with two transparent glass material contacted together, or holes for pure transmission.

26. The system of any of clauses 18-25, wherein the first portion corresponds to regions of the optical element that receive the light from the illumination source and further direct the light toward the patterned substrate to be measured.

27. The system of any of clauses 18-26, wherein the second portion corresponds to regions of the optical element that receive the light reflected from the patterned substrate.

28. The system of clause 27, wherein the second portion corresponds to regions of the optical element that receive first order diffractions of the light reflected from the patterned substrate causing the first order diffractions to pass through the optical element, the first order diffractions comprising information related to the overlay.

29. The system of any of clauses 18-28, wherein the first portion comprises a first quadrant region and a third quadrant region of the optical element; and the second portion comprises a second quadrant region and a fourth quadrant region of the optical element.

30. The system of any of clauses 18-29, wherein the optical element is located within a specified distance from a entrance pupil or a conjugate pupil of a first objective lens near the substrate, or within the specified distance from a conjugate pupil of a second objective lens located away from the substrate.

The concepts disclosed herein may simulate or mathematically model any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-50 nm by using a synchrotron or by hitting a material (either solid or a plasma) with high energy electrons in order to produce photons within this range.

While specific embodiments of the disclosure have been described above, it will be appreciated that the disclosure may be practiced otherwise than as described. While the example structures described above as metrology marks are grating structures specifically designed and formed for the purposes of position measurement, in other embodiments, positions may be measured on structures which are functional parts of devices formed on the substrate.

Many devices have regular, grating-like structures. The terms “mark” and “grating structure” as used herein do not require that the structure be provided specifically for the measurement being performed. An opaque layer is not the only kind of overlying structure that may disrupt measurement of the position of the mark by observing the mark in conventional wavelengths. For example, surface roughness, or a conflicting periodic structure, may interfere with measurement at one or more wavelengths.

In association with the position-measuring hardware and suitable structures realized on substrates and patterning devices, an embodiment may include a computer program containing one or more sequences of machine-readable instructions implementing methods of measurement of the type illustrated above to obtain information about the position of the mark covered by an overlying structure.

This computer program may be executed, for example, by a processor or the like which is dedicated to that purpose. There may also be provided a data storage medium (e.g., semiconductor memory, magnetic or optical disk) having such a computer program stored therein.

Although specific reference may have been made above to the use of embodiments of the disclosure in the context of optical lithography, it will be appreciated that the disclosure may be used in other applications, for example, imprint lithography, and where the context allows, is not limited to optical lithography. In imprint lithography, a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 1-100 nm), as well as particle beams, such as ion beams or electron beams.

The term “lens,” where the context allows, may refer to any one or a combination of various types of optical components, including refractive, reflective, magnetic, electromagnetic and electrostatic optical components. Reflective components are likely to be used in an apparatus operating in the UV and/or EUV ranges.

The breadth and scope of the present disclosure should not be limited by any of the above described exemplary embodiments, but should be defined only in accordance with the following claims and their equivalents.

While the concepts disclosed herein may be used on a substrate such as a silicon wafer, it shall be understood that the disclosed concepts may be used with any type of lithographic systems, e.g., those used for imaging on substrates other than silicon wafers.

The descriptions above are intended to be illustrative, not limiting. Thus, it will be apparent to one skilled in the art that modifications may be made as described without departing from the scope of the claims set out below.

1. An optical tool comprising:
an objective lens configured to direct light from an illumination source to a substrate or a desired location in the optical tool; and
an optical element comprising:
a first portion configured to reflect the light received from the illumination source towards the substrate, and
a second portion configured to transmit at least part of the light redirected from the substrate or the desired location in the optical tool, the first portion having higher coefficient of reflectivity than the second portion, and the second portion having a higher coefficient of transmissivity than the first portion.

2. The optical tool of claim 1, wherein the optical element is positioned at a distance within a specified range from an entrance pupil or a conjugate pupil of the objective lens, wherein the specified range is between the entrance pupil and a conjugate plane, and the distance is measured between a point on the first portion, and the entrance pupil or the conjugate pupil.

3. The optical tool of claim 2, wherein the specified range is a range at which the optical element captures a diffraction pattern caused by the light directed from the first portion onto the substrate and diffracted from the substrate without causing vignetting.

4. The optical tool of claim 1, wherein the first portion has the coefficient of reflectivity between 51% to 100%.

5. The optical tool of claim 1, wherein the first portion comprises a reflective coating formed on a glass substrate where the light from the illumination source is incident on the optical element.

6. The optical tool of claim 1, wherein the first portion comprises one or more mirrors positioned to receive the light from the illumination source and reflect the light to the substrate or the desired location.

7. The optical tool of claim 1, wherein the second portion has the coefficient of transmissivity between 51% to 100%.

8. The optical tool of claim 1, wherein the second portion comprises a transparent glass material, a high transmission coating on a transparent glass material, no coating with two transparent glass materials contacted together, or one or more holes for pure transmission.

9. The optical tool of claim 1, wherein the first portion corresponds to a region of the optical element that receives the light from the illumination source and further directs the light toward the substrate to be measured.

10. The optical tool of claim 1, wherein the second portion corresponds to a region of the optical element that receives the light redirected from the substrate.

11. The optical tool of claim 10, wherein the second portion corresponds to a region of the optical element that receives first order diffractions of the light from the substrate causing the first order diffractions to pass through the optical element.

12. The optical tool of claim 1, wherein the first portion comprises a first quadrant region and a third quadrant region of the optical element; and the second portion comprises a second quadrant region and a fourth quadrant region of the optical element.

13. The optical tool of claim 1, further comprising sensor configured to receive the light transmitted through the second portion of the optical element.

14. The optical tool of claim 13, further comprising a processor configured to determine a physical characteristic of a patterned substrate based on a diffraction pattern detected by the sensor.

15. The optical tool of claim 14, wherein the physical characteristic is a critical dimension of a pattern on the patterned substrate, or overlay between patterns on a first layer and a second layer of the patterned substrate.

16. The optical tool of claim 1, wherein the optical element is located within a specified distance from an entrance pupil or a conjugate pupil of a first objective lens near the substrate, or within the specified distance from a conjugate pupil of a second objective lens located away from the substrate.

17. The optical tool of claim 1, wherein the optical element is a beam splitter.

18. A system for measuring overlay, the system comprising:
an optical element comprising a first portion configured to reflect radiation received from an illumination source, and a second portion configured to transmit at least a part of the radiation redirected from a patterned substrate, the first portion having a higher coefficient of reflectivity than the second portion and the second portion having a higher coefficient of transmissivity than the first portion;
a sensor configured to receive a diffraction pattern of the radiation caused by the radiation being incident of the patterned substrate; and
a processor configured to receive a signal relating to the diffraction pattern from the sensor, and determine overlay associated with the patterned substrate by analyzing the signal.

19. The system of claim 18, wherein the optical element is positioned at a distance within a specified range from an entrance pupil or a conjugate pupil of an objective lens, wherein the specified range is between the entrance pupil and a conjugate plane, and the distance is measured between a point on the first portion, and the entrance pupil or the conjugate pupil.

20. The system of claim 18, wherein the second portion corresponds to a region of the optical element that receives the diffraction pattern from the patterned substrate and the diffraction pattern comprises first order diffractions comprising information related to the overlay.
